(19) United States
(12) Patent Application Publication
(10) Pub. No.: US 2014/0118980 A1
(43) Pub. Date: May 1, 2014

(54) MOUNTING APPARATUS FOR CONVERSION CARD

(71) Applicants: Xiao-Gang YIN, Shenzhen (CN); Jun-Hui WANG, Shenzhen (CN)

(72) Inventors: Xiao-Gang YIN, Shenzhen (CN); Jun-Hui WANG, Shenzhen (CN)

(21) Appl. No.: 13/678,568

(22) Filed: Nov. 16, 2012

(30) Foreign Application Priority Data
Oct. 31, 2012 (CN) 2012104270547

(51) Int. Cl. H05K 7/14

(52) U.S. Cl. CPC H05K 7/1429
USPC 361/796

(57) ABSTRACT

A mounting apparatus for fixing a conversion card to a motherboard of a chassis includes a main board defining an opening and an assistant member. The conversion card is mounted to a bottom surface of the main board. Two inserting pieces extend down from opposite ends of the main board to be detachably engaged in the chassis. The assistant member includes a fixing portion mounted to the bottom surface of the main board and a handle pivotably mounted to the fixing portion. The handle includes an abutting portion and an operation portion opposite to the abutting portion. The operation portion is operated up through the opening to pivot the handle. The abutting portion abuts the motherboard to move the mounting apparatus together with the conversion card away from the motherboard.

### BACKGROUND

1. Technical Field

The present disclosure relates to an apparatus for mounting one or more conversion cards.

2. Description of Related Art

Conversion cards are individually mounted to a bottom of a board fixed to a chassis. In disengaging a conversion card, the board needs to be disengaged from the chassis first, and then the board is moved up to disengage the conversion card from a corresponding connector on a motherboard of the chassis. However, when a size of the board is too great, or the conversion card is firmly engaged in the connector, it will be difficult to disengage the conversion card. Furthermore, when users try to disengage the conversion card from the connector with great power, it may destroy the conversion card and pins of the connector.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of parts of a mounting apparatus, together with two conversion cards.

FIG. 2 is a partially assembled, inverted view of FIG. 1.

FIG. 3 is an inverted, assembled view of FIG. 1.

FIG. 4 is a partially exploded, isometric view of FIG. 1 and a chassis.

FIG. 5 is an assembled, isometric view of FIG. 4.

FIG. 6 is a partially cross-sectional view of FIG. 5, taken along the line VI-VI.

FIG. 7 is similar to FIG. 5, but showing another using state.

FIG. 8 is a partially cross-sectional view of FIG. 7, taken along the line VIII-VIII.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

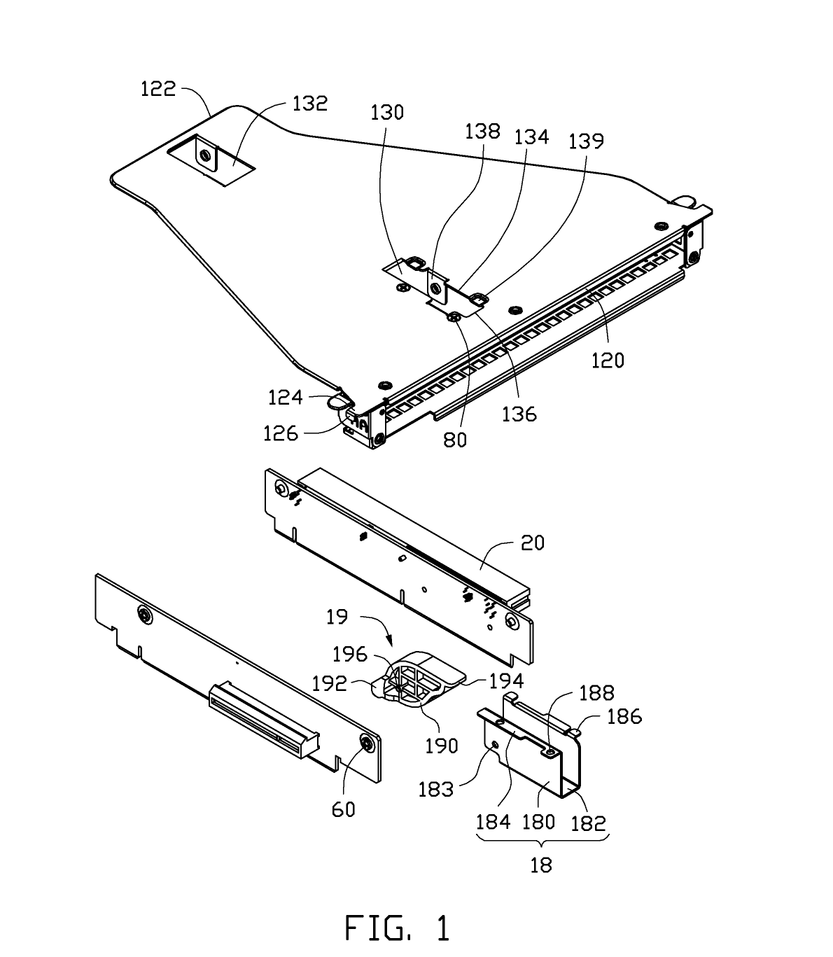

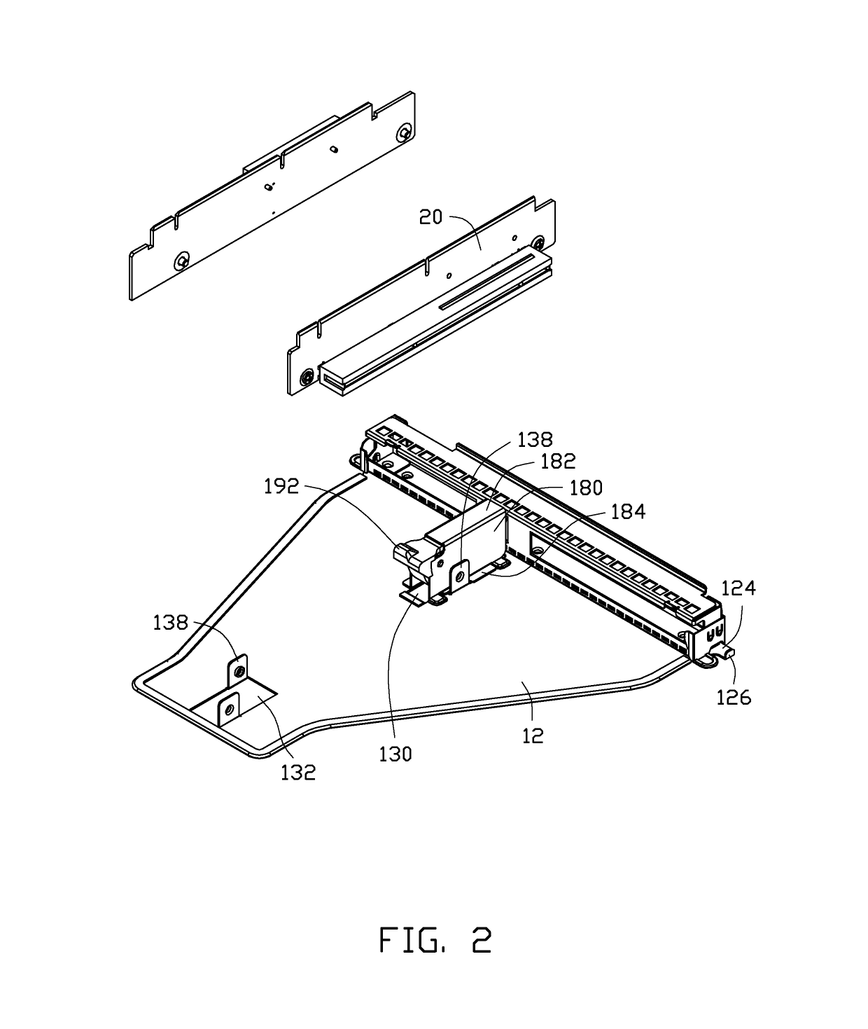

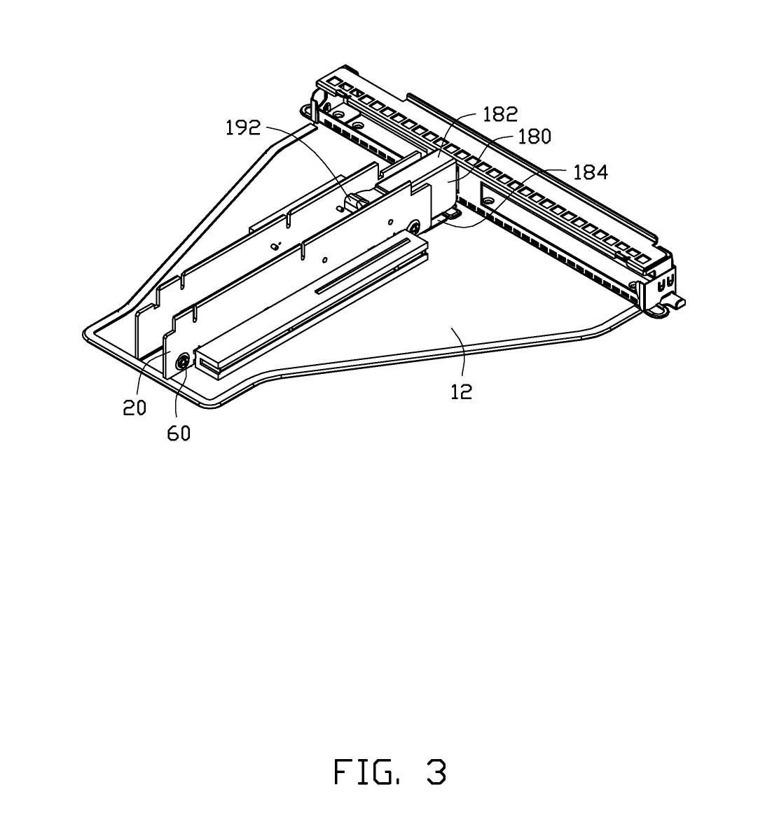

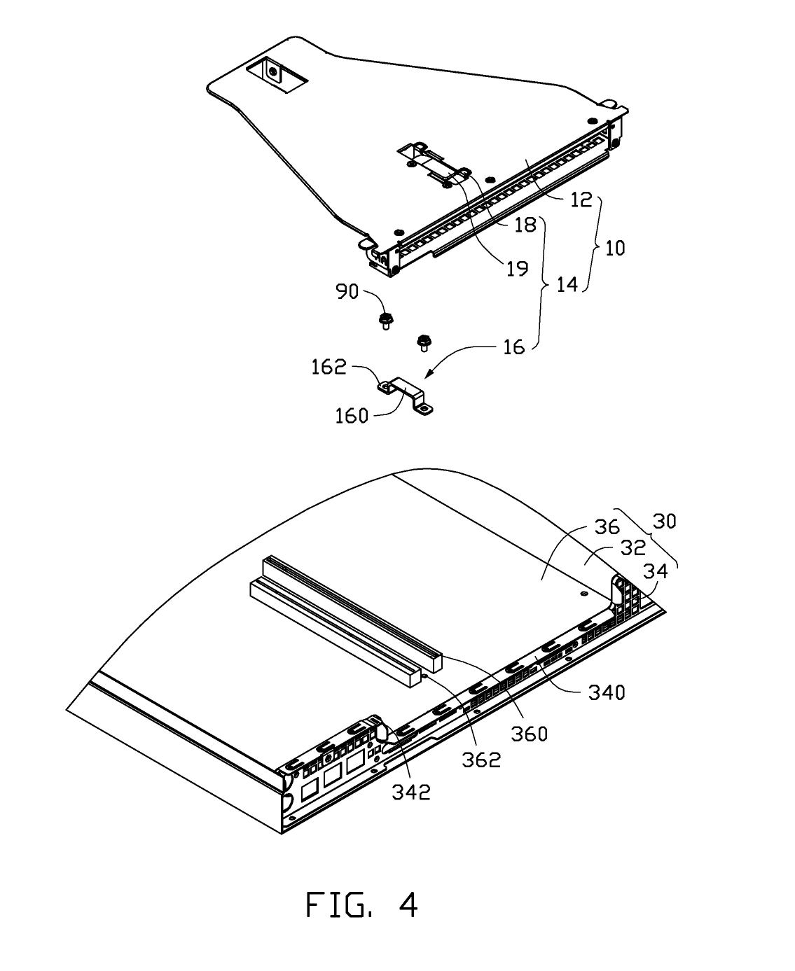

FIGS. 1-4 show an exemplary embodiment of a mounting apparatus 10 for installing two conversion cards 20 to a chassis 30.

The chassis 30 includes a base board 32, a sidewall 34 perpendicularly extending up from an end of the base board 32, and a motherboard 36 mounted on the base board 32. The sidewall 34 defines a cutout 340 extending through a top of the sidewall 34, and two engaging holes 342 in the top of the sidewall 34 and respectively adjacent to opposite ends of the cutout 340. Two parallel connectors 360 are mounted on the motherboard 36. Two through holes 362 are defined in the motherboard 36 between the connectors 360 and are arranged along an extension direction of the connectors 360.

The mounting apparatus 10 includes a main board 12 and an assistant member 14. The main board 12 includes a first side 120, and a second side 122 opposite to the first side 120 and shorter than the first side 120. Two extension pieces 124 extend out from opposite ends of the first side 120. An inserting piece 126 perpendicularly extends down from a distal end of each extension piece 124 opposite to the main board 12. The main board 12 defines a first opening 130 adjacent to a center of the first side 120 and a second opening 132 in front of the first opening 130 and adjacent to the second side 122. The first and second openings 130 and 132 each are bounded by two opposite first walls 134 perpendicular to the first and second sides 120 and 122, and two opposite second walls 136 connecting between corresponding ends of the first walls 134 and are parallel to the first and second sides 120 and 122. A tab 138 perpendicularly extends down from each of the first walls 134. Two recesses 139 communicating with the first opening 130 are defined in a top surface of the main board 12, adjacent to one of the first walls 134 of the first opening 130.

The assistant member 14 includes a base 16, a fixing portion 18, and a handle 19.

The base 16 includes a U-shaped middle portion 160 and two arms 162 extending out from opposite ends of the middle portion 160.

The fixing portion 18 includes two opposite fixing plates 180, a connection plate 182 connected between rear ends of bottoms of the fixing plates 180, and two flanges 184 respectively extending out from top sides of the fixing plates 180. A pivot hole 183 is defined in a front end of each fixing plate 180. Two L-shaped engaging portions 186 extend up from the top side of one of the fixing plates 180, adjacent to front and rear ends of the corresponding flange 184 and then perpendicularly extend away from the other fixing plate 180. The flange 184 opposite to the engaging portions 186 defines two fixing holes 188.

The handle 19 includes a main body 190, an abutting portion 192, and an operation portion 194 extending out from opposite ends of the main body 190. Two pins 196 extend from opposite lateral surfaces of the main body 190 adjacent to the abutting portion 192.

In assembling the handle 19 to the fixing portion 18, the handle 19 is received between the fixing plates 180. The pins 196 are pivotably inserted into the corresponding pivot holes 183, to pivotably mount the handle 19 to the fixing portion 18. The abutting portion 192 extends out of a front end of the connection plate 182.

In mounting the fixing portion 18 together with the handle 19 to the main board 12 from the bottom of the main board 12, the fixing portion 18 is placed between the tabs 138 at the first opening 130. The engaging portions 186 extend through the first opening 130 from the bottom of the main board 12 and are then engaged in the recesses 139, respectively. The flanges 184 are abutted the bottom surface of the main board 12 at opposite sides of the first opening 130. Two screws 80 extend through the main board 12 and then are engaged in the corresponding fixing holes 188 of the flange 184 opposite to the engaging portions 186, thereby fixing the fixing portion 18 and the handle 19 to the bottom of the main board 12. The operation portion 194 is aligned with and below the first opening 130.

The conversion cards 20 are mounted to outer sides of the tabs 138 opposite to the first and second openings 130 and 132 by screws 60 extending through the conversion cards 20 to engage in the corresponding tabs 138. Therefore, the conversion cards 20 are mounted to the bottom of the main board 12, at opposite sides of the fixing portion 18.

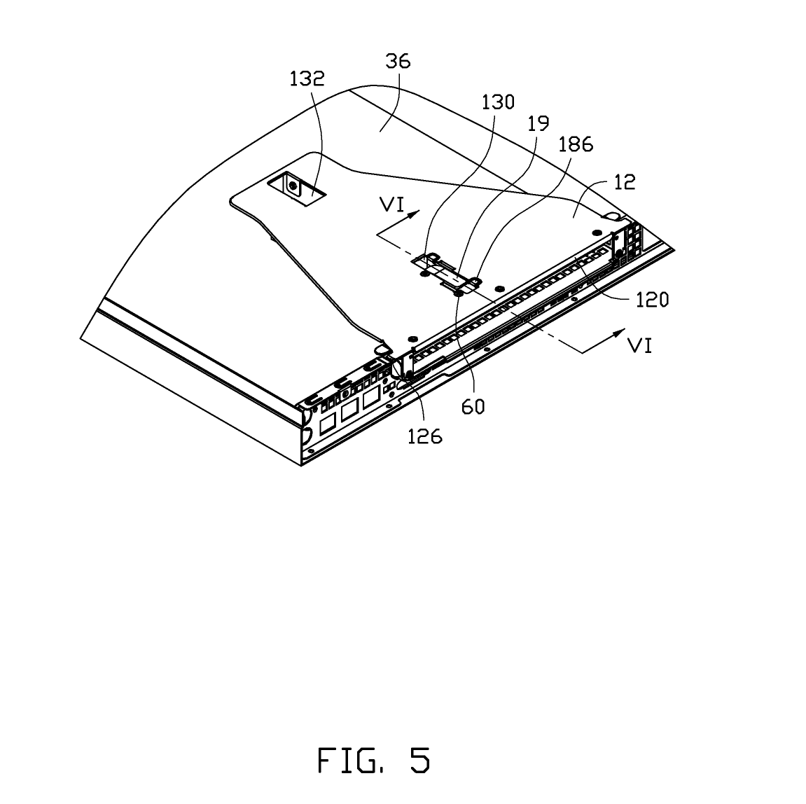

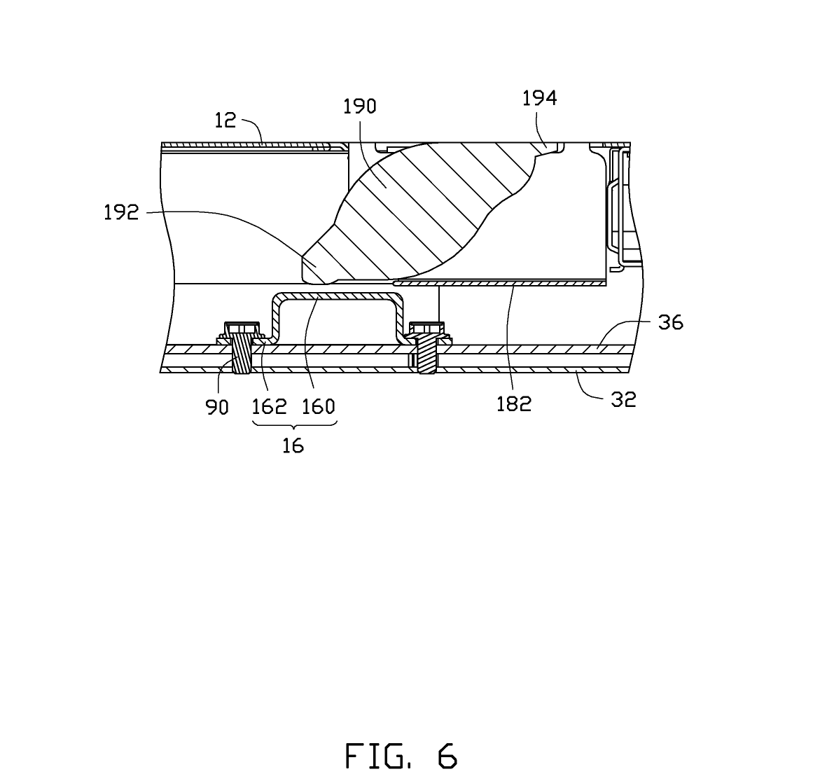

FIGS. 5 and 6 shows that the arms 162 are contacted the top surface of the motherboard 36 between the connectors 360. Two screws 90 respectively extend through the arms 162 and the through holes 362, and then are engaged in the base board 32, to fix the base 16 on the motherboard 36 between the connectors 360.

The conversion cards 20 are inserted into the corresponding connectors 360.

The first side 120 is received in the cutout 340, and the inserting pieces 126 are engaged in the corresponding engaging holes 342, thereby fixing the mounting apparatus 10 with the conversion cards 20 to the chassis 30. At this time, the handle 19 is spaced from the base 16.

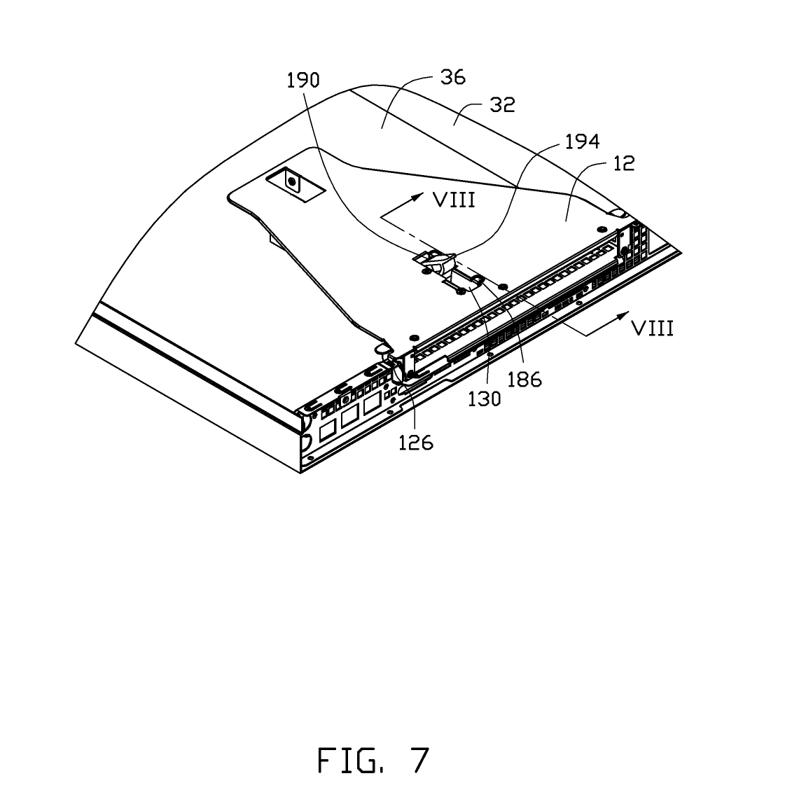

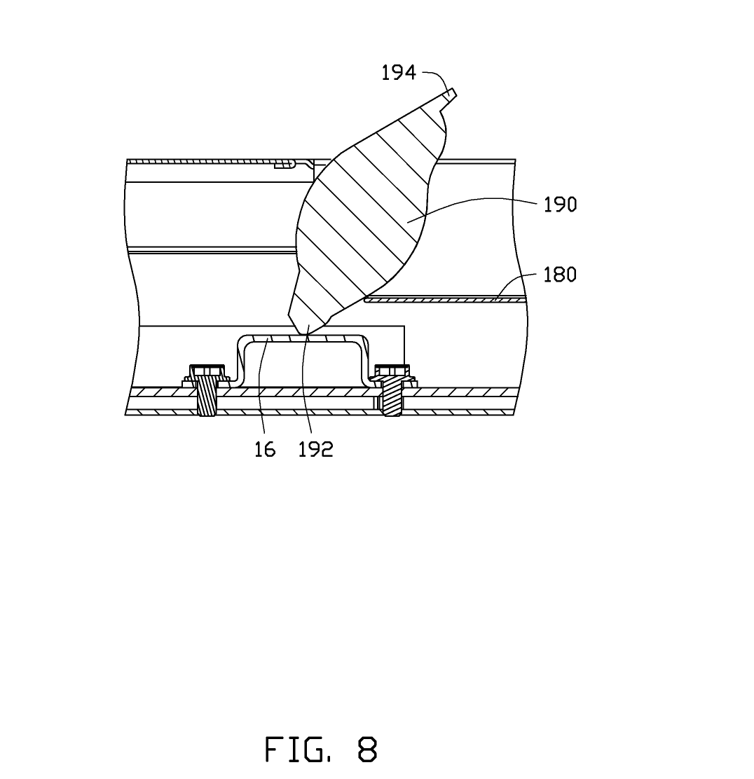

FIGS. 7 and 8 show that when uninstalling the conversion cards 20, the operation portion 194 is moved upward and is exposed out of the first opening 130, thereby pivoting the handle 19. The abutting portion 192 is moved downward, to abut a top of the middle portion 160. The handle 19 is pivoted further. The abutting portion 192 slidably abuts the top of the middle portion 160, thereby lifting the main board 12 with the conversion cards 20. Therefore, the conversion cards 20 are released from the corresponding connectors 360, and the inserting pieces 126 are disengaged from the corresponding engaging holes 342. Thus, the mounting apparatus 10 with the conversion cards 20 may be easily disengaged from the motherboard 36.

In another embodiment, the base 16 may be omitted. At this time, the abutting portion 192 is long enough to slidably abut the motherboard 36 to move the main board 12 with the conversion cards 20 away from the motherboard 36.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting apparatus for mounting a conversion card to a motherboard of a chassis, the mounting apparatus comprising:
a main board to a bottom of which the conversion card is to be fixed, the main board defining a first opening; two inserting pieces extending down from opposite ends of the main board to be detachably inserted into the chassis; and
a handle pivotably mounted to the main board, and comprising a main body, an abutting portion, and an operation portion extending out from opposite ends of the main body, the operation portion aligning with and below the first opening, wherein the handle is pivoted in response to the operation portion being operated up through the first opening.

2. The mounting apparatus of claim 1, further comprising a fixing portion mounted to the main board and in alignment with the first opening, wherein the fixing portion comprises two fixing plates and a connection plate connected between bottom ends of the fixing plates, two pins extend from opposite sides of the main body of the handle and pivotably inserted into the fixing plates.

3. The mounting apparatus of claim 2, wherein the fixing portion further comprises two flanges extending out from top sides of the fixing plates opposite to the connection plate and abutted the bottom of the main board, an engaging portion extends from the top side of one of the fixing plates, the engaging portion extends through the first opening and is engaged with a top surface of the main board, the flange opposite to the engaging portion is fixed to the main board by a fastener.

4. The mounting apparatus of claim 3, wherein the main board defines a recess communicating with the first opening in the top surface of the main board, the engaging portion is received in the recess.

5. The mounting apparatus of claim 1, further comprising a base to be mounted on the motherboard, wherein the base comprises a substantially U-shaped middle portion, and two arms extending out from opposite ends of the middle portion to be fixed to the motherboard, and in case the conversion card is engaged with the motherboard, the abutting portion slidably abuts the middle portion in response to the handle being pivoted to lift the main board together with the conversion card such that the conversion card disengages from the motherboard.

6. The mounting apparatus of claim 1, wherein the main board further defines a second opening, a first tab extends down from a side bounding each of the first and second openings to fix the conversion card.
